(19) United States
(12) Patent Application Publication
(10) Pub. No.: US 2002/0163062 A1
(43) Pub. Date: Nov. 7, 2002

(54) Multiple material stacks with a stress relief layer between a metal structure and a passivation layer

(75) Inventors: Ping-Chuan Wang, New Paltz, NY (US); Robert Daniel Edwards, Marlboro, NY (US); John C. Malinowski, Jericho, VT (US); Vidhya Ramachandran, Essex Junction, VT (US); Steffen Kaldor, New York, NY (US)

Correspondence Address: Graham S. Jones, II, 42 Barnard Avenue, Poughkeepsie, NY, 12601-5023, US

(73) Assignee: International Business Machines Corporation, Armonk, NY (US)

(21) Appl. No.: 09/793,643

(22) Filed: Feb. 26, 2001

(51) Int. Cl. H01L 23/58; H01L 21/302; H01L 29/40; H01L 21/31; H01L 21/461; H01L 23/48

(52) U.S. Cl. 257/641; 257/632; 257/633; 257/635; 257/637; 257/644; 257/642; 257/640; 257/649; 257/650; 257/759; 257/760; 438/724; 438/744; 257/757; 438/791; 438/954; 438/725

(57) ABSTRACT

A structure/method for reducing the stress between a dielectric, passivation layer and a metallic structure comprising coating the metallic structure with a low stress modulus buffer material, and forming the dielectric passivation layer covering the low stress modulus buffer material. The low stress modulus buffer material is composed of a layer of a polymeric material selected from at least one of the group consisting of a hydrogen/alkane SQ (SilsesQuioxane) resin, polyimide, and a polymer resin. The dielectric, passivation layer is composed of at least one layer of a material selected from at least one of the group consisting of silicon oxide and silicon nitride. A protective layer is formed over the dielectric, passivation layer. The low stress modulus buffer material has a thermal coefficient of expansion between that of the metallic structure and that of the dielectric passivation layer. In particular, the dielectric passivation layer between the metallic structure and the low stress modulus buffer material has a thermal coefficient of expansion between about 5 ppm/° C. and about 20 ppm/° C.

### BACKGROUND OF THE INVENTION

1. Field of the Invention

This invention relates to a method and structures using multi-layer passivation and protection layers formed over a substrate and an electrical conductor formed thereon, and more particularly to stacks formed of mechanically compatible materials employed in devices, such as microelectronic semiconductor devices.

2. Description of Related Art

Where diverse materials are formed in successive layers in thin film devices, differences in mechanical characteristics such as incompatible Coefficients of Thermal Expansion (CTE) lead to the problems of excessive stress causing cracking of one or more layers. As the state of the art progresses, dimensional requirements continue to shrink, and new combinations of materials are employed, stress related cracking problems arise in different ways and unique solutions need to be employed to overcome the fundamental problems which exist because of intrinsic mechanical forces exerted by the materials in terms of stress as a function of relative elongation as defined by the Young's modulus.

An example of the problem of CTE mismatch causing stress cracks is shown in FIGS. 1A and 1B. FIG. 1A shows a schematic cross section of a prior art device 10 comprising a silicon semiconductor substrate or the like upon which is formed a metallic structure 14 in the form of a metal conductor line composed of aluminum or a similar metal. Note that metal conductor lines such as metal 14 with a thickness larger than several microns (μm) are used for high-Q inductor rings in high-performance passive devices. These thick lines 14 are formed of a metal, e.g. Al, Cu, Ag, or Au.

Conformally covering the metallic structure 14 is an inorganic, dielectric, passivation layer(s) 18 (e.g. a thin silicon oxide layer and/or silicon nitride), which protect the metallic structure 14 from moisture and provides electrical insulation. Covering the inorganic, dielectric, passivation layer(s) 18 is a polyimide layer 20 which is shown as being conformal to the exterior of the inorganic, dielectric, passivation layer 18.

The thick metallic conductor lines 14 are typically at the top level of an integrated circuit chip 12, covered by a silicon oxide and/or a silicon nitride inorganic, dielectric, passivation layer 18 and a polyimide protection layer 20 for mechanical and environmental protection, as shown schematically in FIG. 1A.

Due to the thermal expansion mismatch between a metallic conductor line 14 and inorganic, dielectric, passivation layer 18, a mechanical stress is generated in the stack of layers 14/18/20, when the system is subject to temperature changes. This creates large stress at the interface between the metal line 14 and the inorganic, dielectric, passivation layer 18 and may fracture the oxide/nitride passivation layers 18. FIG. 1B is a schematic drawing illustrating the cracking produced by thermal cycling of a structure 10 based upon experimental observations. FIG. 1B shows the device of FIG. 1A which has developed three readily identifiable crack sites 18A, 18B and 18C including the major crack sites 18B on top and two minor crack sites 18A and 18C on the side walls. The crack sites upon which this drawing is based were induced by repetitive temperature cycles between −160° C. and 180° C.

Such cracks may have direct impact to the reliability of the metallic layer 14 in this type of structure, as they provide paths for oxygen/moisture to pass through the cracks in the passivation layer 18 to attack the metallic line 14. In particular, since copper (Cu) is anticipated to be used for high-Q inductor material, the oxidation/corrosion of Cu at the cracked sites is certainly a cause of great concern since it is far more vulnerable to oxidation/corrosion than aluminum.

U.S. Pat. No. 5,795,833 of Yu et al. for “Method for Fabricating Passivation Layers over Metal Lines” shows a substrate such as a semiconductor wafer covered by an insulating layer on which metal lines (e.g. tungsten (W), polycide, aluminum (Al) alloys) are formed. The metal lines and the insulating layer are covered by a first silicon nitride layer, comprising a thin Plasma Enhanced Silicon Nitride (PE-SiN) layer which serves as a corrosion protective, moisture barrier at the bottom of the metal lines because of the conformal nature of the plasma enhanced process used and because the SiN layer is thin-under about 1,000 Å thick. A silicon oxide layer which can be Plasma Enhanced silicon oxide (PE-OX) is formed over the first SiN layer with a thickness from about 4,000 Å to about 9,000 Å which thickness range “is very important because it minimizes stress between the metal lines . . . and the passivation layers . . . .” A second silicon nitride layer with a thickness from about 4,000 Å to about 7,000 Å is formed over the silicon oxide layer. An insulating layer (preferably polyimide or epoxy) is formed over the second nitride layer.

U.S. Pat. No. 6,103,639 of T. Chang et al. for “Method for Reducing Pin Holes in a Nitride Passivation Layer” describes a metal (Al) conductor formed on a dielectric layer. The conductor and the dielectric layer are in turn covered by an oxide layer. The oxide layer “ . . . serves as a buffer layer to eliminate stress between the metal layer and a subsequent silicon nitride layer.”

U.S. Pat. No. 5,955,200 of K.-M. Chang et al. for “Structure for Reducing Stress Between Metallic Layer and Spin-On-Glass Layer” describes a structure for reducing the stress between a HSQ (Hydrogen SilsesQuioxane) dielectric layer and metal elements formed from a metal layer. Note that HSQ is also known as HSSQ (Hydrogen SilSesQuioxane). The structure comprises the metal elements, a stress buffer (an ECR silicon rich oxide layer) above the metal layer, and a spin-on-glass layer above the stress buffer. If the spin-on-glass layer is a dielectric material capable of producing tensile stress, the stress buffer layer is made from a material capable of generating compressive stress. On the contrary, if the spin-on-glass layer is a dielectric material capable of producing compressive stress, the stress buffer layer is made from a material capable of generating tensile stress.

U.S. Pat. No. 4,491,622 of Butt for “Composites of Glass-Ceramic to Metal Seals and Method of Making the Same” describes a composite structure. A component comprise a first metal or alloy layer covered on its top surface with a first thin refractory silicon oxide layer. A second component comprises a separate metal or alloy layer which has a second thin refractory silicon oxide layer on the bottom surface thereof. The thin refractory silicon oxide layers of the two components are bonded together by a glass or ceramic layer which has a Coefficient of Thermal Expansion (CTE) which is closely matched to that of the first and second metal or alloy components, whereby thermal stress between the metal or alloy components and the bonding means is substantially eliminated. The glass or ceramic layer also electrically insulates the first component from the second component.

U.S. Pat. No. 4,654,269 of Lehrer for “Stress Relieved Intermediate Insulating Layer for Multilayer Metallization” discloses a stress relieved intermediate insulating layer consisting of one or more layers of spun-on glass formed from TEOS lying over a metallization pattern (source, drain, and gate contacts in an MOS device). Each spun-on glass layers is heated until it develops cracks from thermal stress due to the heat treatment. Then the next layer is applied thereby filling the cracks. In addition, the second layer of spun-on glass is planar. The cracks in the spun-on layers are then filled with a glass layer formed by CVD deposition of silicon dioxide or by LPCVD.

U.S. Pat. No. 6,051,511 of Thakur et al. for “Method and Apparatus for Reducing Isolation Stress in Integrated Circuits” reduces stress resulting from silicon nitride (Si₃N₄) by forming an oxidation mask with Si₃N₄ having a graded concentration of silicon. The grading change of the silicon content in the Si₃N₄ is achieved by varying the amount of hydride, such as dichlorosilane (DCS), mixed with ammonia. The Si₃N₄ is graded linearly or non-linearly.

U.S. Pat. No. 5,970,364 of Huang et al. for “Method of Nitride-Sealed Oxide-Buffered Local Oxidation of Silicon” describes forming an isolation region (LOCOS) in an integrated circuit. Over a pad layer on a semiconductor substrate, an oxidation masking layer. The pad layer relieves stress from the oxidation masking layer. Portions of the oxidation masking layer and the pad layer are then patterned and etched. A thermally grown first silicon oxide layer is formed on the substrate. A second silicon oxide spacer is formed on a sidewall of the pad layer and the oxidation masking layer. After forming a Si₃N₄ spacer on a surface of the second silicon oxide spacer, the substrate is thermally oxidized to form the LOCOS region in the substrate.

U.S. Pat. No. 5,144,391 of Iwata et al. for “Semiconductor Device Which Relieves Internal Stress and Prevents Cracking” describes a semiconductor device with a semiconductor thin film, and first and second insulator films formed so that the semiconductor thin film is sandwiched therebetween. Graded layers, containing a constituent element of the semiconductor thin film and impurities, have the amount of the impurities decreased in the direction of the semiconductor thin film, interposed between the semiconductor thin film and the insulator films to relax internal stress at junction interfaces between the semiconductor thin film and the insulator films and to prevent cracking at the interfaces.

Commonly assigned, U.S. Pat. No. 6,130,472 of Feger et al. for “Moisture and Ion Barrier for Protection of Devices and Interconnect Structures” forms an organic dielectric interconnect structure (which contains conductors comprising vias and metal lines and metal pads) on the surface of a semiconductor substrate. The structure is formed of a material with a dielectric constant less than SiO₂ such as Diamond Like Carbon (DLC), fluorinated DLC, sesquisiloxanes (HSSQ aka HSQ), methyl sesquisiloxanes (MSSQ), polyimides, parylene-N, benzocyclobutanes, fluorinated polyimides, poly(arylene ethers) parylene-F, Teflon AF, poly(naphthalenes), poly(norbones), foams of polyimides, xerogels, porous PTFE, and porous MSSQ. Over the organic dielectric interconnect structure and the conductors is formed a polymer layer in direct contact with the metal lines. The polymer layer is composed of either a fluoropolymer (e.g PTFE), a PolyChloroFluoroPolymer (PCFP) or a hydrocarbon.

Some of the above prior art patents involve packaging levels which are employed to reduce the stress on semiconductor dies which are mounted on ceramic modules. T. Chang et al. U.S. Pat. No. 6,103,639 suggests use of silicon oxide as a buffer material to deal with stress between an aluminum metal conductor and an upper silicon nitride layer.

Another prior art patent uses additional (or graded) silicon oxide or a nitride layer processed at a different temperature to “counteract” the stress in the metal stack.

### SUMMARY OF THE INVENTION

None of the prior art patents listed above used elastic materials (like the low stress modulus polymer material of this invention) with low stress modulus and intermediate CTE (Coefficient of Thermal Expansion) between metal and silicon oxide to provide a film that buffers or absorbs the stress transferred between a thick metal and a thin silicon oxide or silicon nitride layer on top. The K.-M. Chang et al. U.S. Pat. No. 5,955,200 suggests using silicon oxide as a stress buffer layer between a metal conductor and an HSQ spin on glass (SOG) layer, which is the opposite of the concept of this invention which is to overcome the stress which exists when silicon oxide is formed over a metal conductor. As will be seen below that approach is the opposite of the present invention.

In accordance with this invention a structure/method for reducing the stress between a dielectric, passivation layer and a metallic structure comprising coating the metallic structure with a low stress modulus buffer material, and forming the dielectric passivation layer covering the low stress modulus polymeric material. The low stress modulus buffer material is composed of a layer of a material selected from at least one of the group consisting of polymers such as polyimide, a polymer resin, and a hydrogen/alkane-SQ family of resins (R1-SQ where R1 is a member of the alkane (paraffin) series of hydrocarbons and SQ is a SilsesQuioxane) which includes but is not limited to Hydrogen SilsesQuioxane (HSQ) and Methyl SilsesQuioxane (MSQ). The dielectric, passivation layer is composed of at least one layer of a material selected from at least one of the group consisting of silicon oxide and silicon nitride. A protective layer of polyimide or the like is formed over the dielectric, passivation layer. Preferably, the passivation and protective layers are formed over a metallic structure such as a copper, aluminum, gold or silver conductor formed on a layer above or directly upon the surface of a doped silicon substrate.

Preferably the low stress modulus buffer material has a thermal coefficient of expansion between that of the metallic structure and that of the dielectric passivation layer. In particular the dielectric passivation layer between the metallic structure and the low stress modulus buffer material has a thermal coefficient of expansion between about 5 ppm/° C. and about 20 ppm/° C.

### DESCRIPTION OF THE DRAWINGS

The foregoing and other aspects and advantages of this invention are explained and described below with reference to the accompanying drawings, in which:

FIG. 1A shows a schematic cross section of a prior art device comprising a silicon semiconductor substrate upon which is formed a metallic conductor conformally covered with an inorganic, dielectric, passivation layer which is in turn covered by a conformal, polyimide layer.

FIG. 1B shows the device of FIG. 1A which has developed three readily identifiable crack sites including a major crack site on top and two minor crack sites on the side as the result of by repetitive temperature cycling.

FIGS. 2A-2C show three embodiments of a device (integrated circuit) with an intermediate low stress modulus buffer layer formed on top and on the sides of a metal structure (conductor) on a substrate (silicon semiconductor) in accordance with this invention with one or more inorganic, dielectric, passivation layer(s) formed over the surfaces of the stress modulus buffer layer.

FIGS. 3A-3C show three embodiments of a device (integrated circuit) with an intermediate, low stress modulus, buffer layer formed on top of a metal structure (conductor) on a substrate (silicon semiconductor) in accordance with this invention with one or more inorganic, dielectric, passivation layer(s) formed above the low stress modulus buffer layer and on the sides of the metal structure.

FIGS. 4A-4C show three embodiments of a device (integrated circuit) with an intermediate, low stress modulus, buffer layer formed on top, on the bottom and on the sides of a metal structure (conductor) on a substrate (silicon semiconductor) in accordance with this invention with one or more inorganic, dielectric, passivation layer(s) formed around the stress modulus buffer layer.

### DESCRIPTION OF THE PREFERRED EMBODIMENT

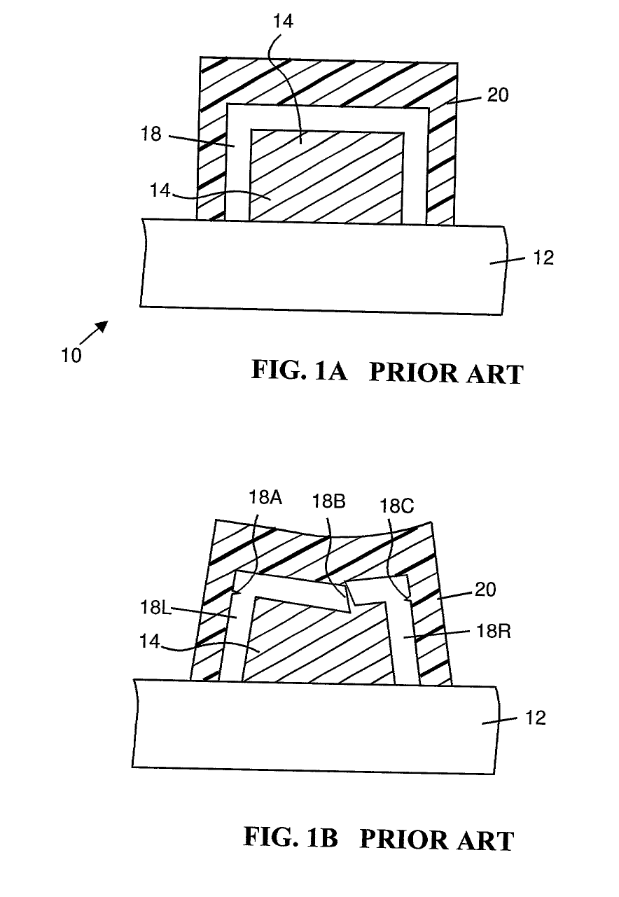

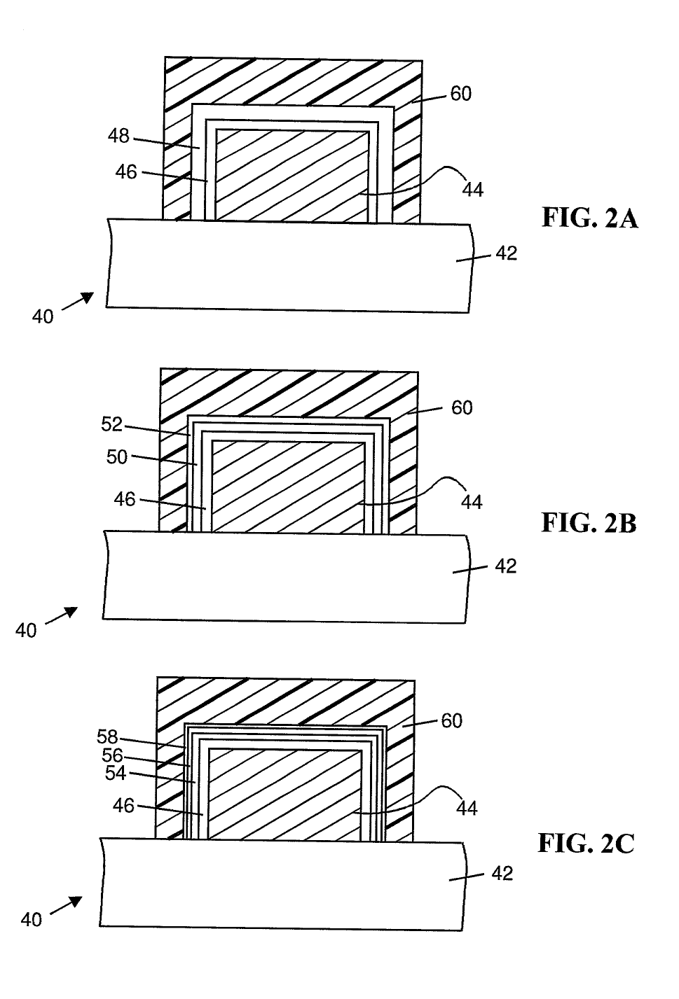

FIGS. 2A-2C, show three different modifications of the structure of FIG. 1A which are embodiments of a device 40 (integrated circuit) with an intermediate, low stress modulus, buffer layer 46 formed on the top surface and sides of a metal structure 44 (conductor) which is formed on a substrate 42 (e.g. a silicon semiconductor, silicon dioxide or a dielectric layer, etc.) in accordance with this invention. One or more inorganic, dielectric, passivation layer(s) 48 are formed above and on the sides of the low stress modulus buffer layer 46 as described in more detail below with respect to the individual embodiments.

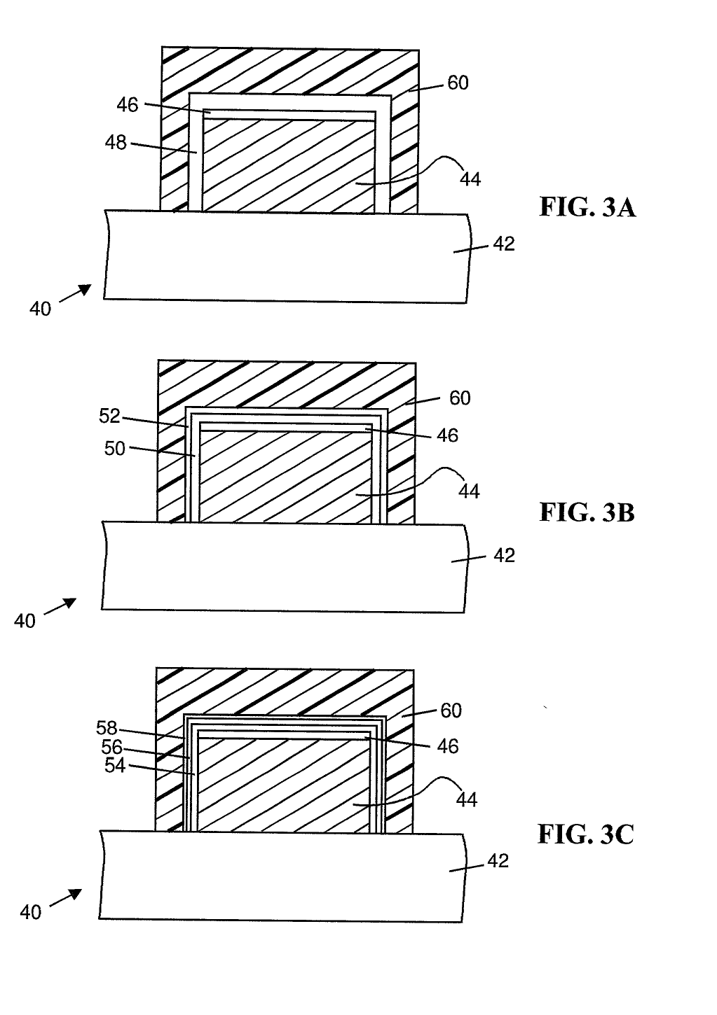

FIGS. 3A-3C, show three different modifications of the structure of FIG. 1A which are embodiments of a device 40 (integrated circuit) with an intermediate, low stress modulus, buffer layer 46 formed on the top surface and sides of a metal structure 44 (conductor) which is formed on a substrate 42 (e.g. a silicon semi-conductor, silicon dioxide or a dielectric layer, etc.) in accordance with this invention. One or more inorganic, dielectric, passivation layer(s) 48 are formed above the low stress modulus buffer layer 46 and on the sides of the metal structure 44, as described in more detail below with respect to the individual embodiments of FIGS. 2A-2C.

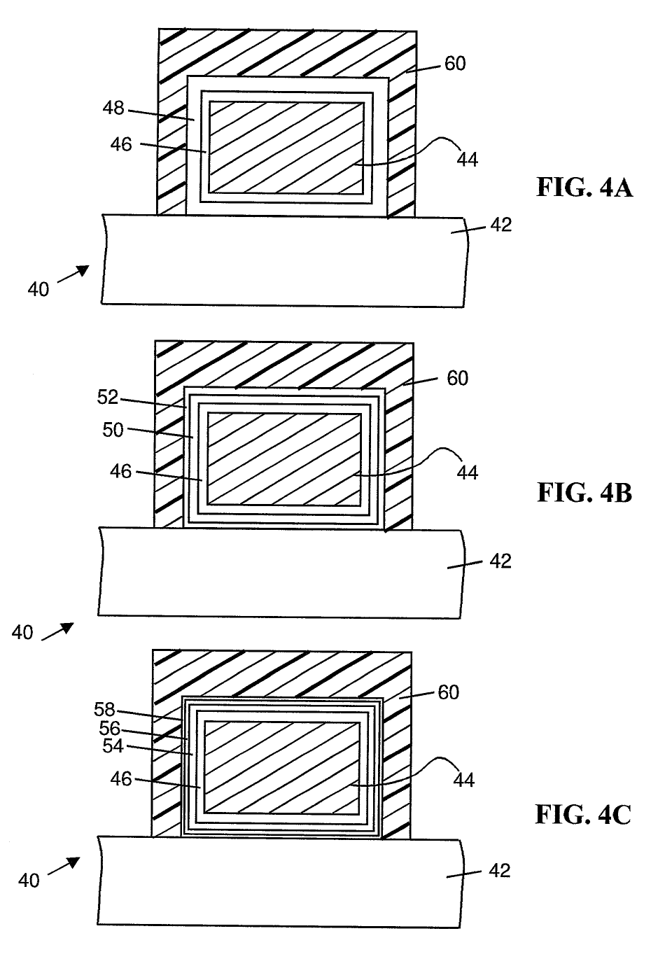

FIGS. 4A-4C, show three different modifications of the structure of FIG. 1A which are embodiments of a device 40 (integrated circuit) with an intermediate, low stress modulus, buffer layer 46 formed surrounding the metal structure 44 (conductor) which is formed on a substrate 42 (e.g. a silicon semiconductor, silicon dioxide or a dielectric layer, etc.) in accordance with this invention. One or more inorganic, dielectric, passivation layer(s) 48 are formed surrounding the low stress modulus buffer layer 46, as described in more detail below with respect to the individual embodiments of FIGS. 2A-2C.

In accordance with this invention the devices 40 of FIGS. 2A-2C, 3A-3C and 4A-4C are designed to prevent occurrence of cracks in the inorganic, dielectric, passivation layer(s) above the thick metallic structure (line) 44. The improved method of this invention involves the step of forming a low stress modulus buffer layer 46 covering surfaces of the metallic structure 44. In FIGS. 2A-2C, the low stress modulus buffer layer 46 covers the top and sides of the metallic structure 44. In FIGS. 3A-3C, the low stress modulus buffer layer 46 covers only the top of the metallic structure 44. In FIGS. 4A-4C, the low stress modulus buffer layer 46 covers the top, bottom, and sides of the metallic structure 44.

The next step is to form one or more inorganic, dielectric, passivation layer(s) over the device 40. In FIGS. 3A-3C, the inorganic, dielectric, passivation layer(s) cover the top of the low stress modulus buffer layer 46 and the sides of metallic structure 44.

In the embodiments shown in FIGS. 2A, 3A and 4A, the inorganic, dielectric, passivation layer 48 is a layer/film selected from the group of materials consisting of silicon oxide and silicon nitride that is formed over the intermediate, low stress modulus, buffer layer 46.

In FIGS. 2B, 3B and 4B, an inorganic, dielectric, passivation (SiO₂/Si₃N₄ or (Si₃N₄/SiO₂) bilayer 50/52 is formed over all surfaces of the low stress modulus buffer layer 46 and in the case of FIG. 3B, on the sides of the metallic structure 44. In a first alternative embodiment, the inorganic, dielectric, passivation bilayer 50/52 (formed over the low stress modulus buffer layer 46) comprises a lower silicon oxide layer 50 which is covered with an upper silicon nitride layer 52. In a second alternative embodiment, the inorganic, dielectric, passivation bilayer 50/52 (formed over the low stress modulus buffer layer 46) comprises a lower silicon nitride layer 50 which is covered with an upper silicon oxide layer 52.

In FIGS. 2C, 3C, and 4C a third set of alternative embodiments are inorganic, dielectric, passivation silicon oxide layer 54, a silicon nitride layer 56 and a silicon oxide layer 58 which are formed over the low stress modulus buffer layer 46, and in the case of FIG. 3C, on the sides of the metallic structure 44.

In FIGS. 2A-2C, 3A-3C and 4A-4C, the respective top dielectric passivation layers 48, 52 and 58 of devices 40 are covered by an overcoat/protection layer 60, preferably composed of polyimide which provides overall protection for the devices 40.

The low stress modulus buffer layer 46 has an intermediate CTE value between the CTE value of the metallic structure 44 and the CTE value of the passivation layers 48, 50, 54 and any other passivation layers formed thereabove. The low stress modulus buffer layer 46 absorbs stress between the thick metallic structure 44 and the inorganic, dielectric, passivation layer 48 thereabove, to provide significant reduction in the stress in the interface passivation layers 48, 50, 54 and any other passivation layers formed thereabove.

The intermediate, low stress modulus, buffer layer 46 is capable of inhibiting cracking of the structure in which it is incorporated because the CTE value thereof is intermediate the CTE values of the materials thereabove and therebelow and the buffer layer has a low Young's modulus which is appropriate for absorbing the stress without cracking.

The intermediate, low stress modulus, buffer layer 46 (between the metal and the passivation layer) can be made of a thin layer of a polymer material. For example the low stress modulus, buffer layer 46 may be a hydrogen/alkane-SQ family material, such as HSQ or MSQ (methyl sesquisiloxanes.)

The hydrogen/alkane SQ (SesQuisiloxane) family of spin-on-glass (SOG) materials is characterized by the general formula R1-SesQuisiloxane (R1-SQ), where RI may one of several radicals of hydrogen or the alkane family of hydrocarbons including but not limited to the hydrogen radical, and carbon bonded radicals such as a member of the alkane (paraffin) family of methyl, ethyl, butyl, propyl radicals. For example, RI may be a methyl radical CH₃, an ethyl radical C₂H₅, a butyl radical C₃H₇, or a propyl radical C₃H₉, etc.

Alternatively, the low stress modulus, buffer layer 46 can be composed of polyimide. Another alternative choice for the buffer layer 46 is a low stress modulus thin film polymer with a small stress modulus less than 20 GPa and an intermediate CTE at about −50° C. to about 150° C. of about 5 ppm/° C. to about 20 ppm/° C., and protective interlayer dielectric resin coatings, etc.) which have a low mechanical modulus and thus higher compliance, and it can be fabricated using existing techniques.

The elastic nature of low stress modulus buffer film 46 can be used to absorb the stress transfer between the metallic structure 44 and oxide/nitride layers by carrying the stress at the interface. Consequently, the oxide/nitride layer 48 is protected from the CTE mismatch between the oxide/nitride, inorganic, dielectric, passivation layer 48 and the thicker metallic structure 44 beneath the low stress modulus buffer film 46 so that stress-induced cracking can be avoided.

Although the CTE mismatch among the metallic conductor 44 (Al, Cu, etc.), the inorganic passivation layer(s) 48 (SiO₂/Si₃N₄, silicon oxide, etc.), overcoat/protective layer 60 (polyimide), and the “soft” buffer film 46 is very large, the low Young's modulus of the buffer film 46 relieves the stress transferred to the inorganic passivation layer 48 as shown by the widely used engineering analysis FEM (Finite Element Modeling) software which employs well established elastic theoretical analysis algorithms.

TABLE I

| | Young's Modulus | Thermal Coefficient of Expansion |
|---|---|---|
| | E(GPa) | α (ppm/° C.) |
| Aluminum | 83 | 23.5 |
| Copper | 130 | 17 |
| Silver | 83 | 19.1 |
| Gold | 78.5 | 14.2 |
| Si | 168 | 3 |
| SiO₂ | 72 | 0.6 |
| FSG | ˜100 | ≦10 |
| SiNₓ | 300 | 5 |
| HSQ | 3 | 22 |
| Polyimide | 8.3 | 3.8 |
| (BPDA-PDA) | | |

We have evaluated the concept of a low stress modulus buffer film 46 by extensive FEM finite element modelings. FIG. 2A shows the structure used in the modelings, where the low stress modulus buffer film 46 (between an Al layer 44 and SiO₂ layer 48) is made of the hydrogen member of the hydrogen/alkane-SQ family, i.e. HSQ, a low stress material with CTE=22 ppm/° C. and a Young's modulus E=3.1 GPa. For convenience, we treat the structure as stress-free at room temperature, and analyze the stress distribution at 180° C. using elastic model.

Results of the modeling revealed the contours of σₓₓ (stress in x-direction) which causes a crack in a silicon oxide layer 18 in FIGS. 1A and 1B. The result of a model without a buffer film is a tensile stress as high as 220 MPa which is concentrated in the middle of the silicon oxide passivation layer on top of an aluminum metallic conductor 14.

Referring to FIG. 2A, the result with a 1 im-thick buffer film 46 of a member of the hydrogen/alkane-SQ family is that the tensile stress in the silicon oxide layer 48 is reduced to only about 140 MPa, and it is more uniformly distributed along the silicon oxide passivation layer. The result with a 2 im-thick buffer film 46 of a member of the hydrogen/alkane-SQ family is that the tensile stress in the silicon oxide layer 48 is further reduced to about 130 MPa and even more uniformly distributed.

### Elastic Modeling

In an analysis made employing FEM (Finite Element Method) software (see J. N. Reddy, Texas A & M University “Introduction to the Finite Element Method, Second Edition, (1993) 896 pages implemented in software supplied by Ansys, Inc., models clearly show that a HSQ (Hydrogen SilsesQuioxane) buffer film 46 layer of FIGS. 2A-2C both reduces the magnitude of the normal stress, σₓ^{ox}, and eliminates the large stress concentration that occurs in FIGS. 1A and 1B near the center of the silicon oxide layer 18 when no buffer film is present.

Referring again to FIGS. 2A-2C, an important point is that the normal stress in the buffer film 46, σₓ^{buff}, may exceed the elastic limit of HSQ thus causing yielding and/or cracking which might increase, not decrease, the stress in the silicon oxide layer. In experiments involving HSQ, Eric Liniger observed that HSQ fails in a brittle fashion and exhibits little or no yielding.

Thus we should be looking at the maximum stress levels in our model to ensure that they are not high enough to cause fracture in the HSQ film, i.e. do not exceed the ultimate tensile strength. While this value for HSQ is not readily found in the literature, it can be estimated from the hardness values reported in a paper by Robert Cook et al. [Robert F. Cook, Eric G. Liniger, David P. Klaus, Eva E. Simonyi, and Stephan A. Cohen. “Properties Development During Curing of Low Dielectric-Constant Spin-on Glasses.” Mat. Res. Soc. Symp. Proc. Vol. 511, P. 33, (1998)]

Depending on curing temperature, the hardness of HSQ measured by indentation experiments was found to vary from about 0.8 GPa to about 2.2 GPa. Using a empirical relationship between hardness and yield strength as follows:

Hardness or pressure˜2.5 σ_{yield}

With reference to Courtney, Mechanical Behavior of Materials, page 31, we find the yield strength to range from about 320 MPa to about 900 MPa. It appears that the HSQ will fracture if this stress value is exceeded.

From our modeling results, we find that the stress in the HSQ low stress modulus buffer layer 46 is very low. This is due to HSQ's low elastic modulus, E, of 3.1 GPa. Even for a relatively large strain, the stress remains at low levels as seen from Hooke's law: σ=Eε

Based on our FEM modeling the Table II provides as follows:

TABLE II

| HSQ buffer layer | σₓ^{avg} | Std.dev(σₓ) | σₓ^{max} |
|---|---|---|---|
| 1 μm | 17 MPa compress | 8 MPa | 23 MPa compress |
| 2 μm | 14 MPa compress | 5 MPa | 23 MPa compress |

FSG = (SiO₂)x(Si₂O₃F₂)(1 − x)
XSQ = X-SilsesQuioxanes are XSiO_{1.5} where X = H, CH₃, C₂H₅, C₃H₇, etc.

In both cases, the normal stress in the low stress modulus buffer film 46 falls well below our estimate of the ultimate tensile strength with a safety factor of >10.

### HSO Film Stress

The film stress which exists in HSQ after processing/curing is about 60 MPa tensile at room temperature. Upon heating to 180° C. (the high temperature reached during a standard temperature cycle stressing), this tensile stress will diminish, and the overall stress in the buffer film 16 will decrease. Upon cooling to −160° C. (the low temperature reached during a standard temperature stressing), the tensile stress increases to −120 MPa. Adding this value to the stress expected due to thermal contraction, −20 MPa tensile, the stress remains well below the tensile strength of HSQ providing a safety factor of about 2.3-6.4.

In summary, HSQ has a very low elastic modulus and thus experiences low thermal stress levels as compared with its ultimate tensile strength. For this reason, our elastic FEM modeling is justified.

Based on these results of FEM (Finite Element Modeling) we believe that the low stress modulus buffer film 46 of this invention is effective in reducing the concentrated mechanical stress in the protecting the passivation layer 48 of the kind employed a conventional thick metallic stack like analog metallic for high-Q inductor rings. Therefore, the buffer film 46 of this invention can prevent cracks in a passivation layer 48 thereby improving the mechanical integrity of these structures.

### Coefficient of Thermal Expansion of Buffer Layer

The CTE of the buffer layer is ideally midway between the metallic structure 44 and the dielectric passivation layer 48. Preferably the CTE a is between about 5 ppm/° C. and about 20 ppm/° C.

While this invention has been described in terms of the above specific embodiment(s), those skilled in the art will recognize that the invention can be practiced with modifications within the spirit and scope of the appended claims, i.e. that changes can be made in form and detail, without departing from the spirit and scope of the invention. Accordingly all such changes come within the purview of the present invention and the invention encompasses the subject matter of the claims which follow.

Having thus described the invention, what is claimed as new and desirable to be secured by Letters Patent is as follows:

1. A method of reducing the stress between a dielectric, passivation layer and a metallic structure comprising the steps as follows:
coating the metallic structure with a low stress modulus buffer material, and
forming the dielectric passivation layer covering the low stress modulus buffer material.

2. The method of claim 1 wherein the low stress modulus buffer material is composed of a layer of a material selected from at least one of the group consisting of polyimide, a polymer resin, and members of the hydrogen/alkane SQ (SilsesQuioxane) family.

3. The method of claim 1 wherein the dielectric, passivation layer is composed of at least one layer of a material selected from at least one of the group consisting of silicon oxide and silicon nitride.

4. The method of claim 1 wherein:
the low stress is composed of a layer of a material selected from at least one of the group consisting of polyimide, a polymer resin, and members of the hydrogen/alkane SQ (SilsesQuioxane) family, and
the dielectric, passivation layer is composed of at least one layer of a material selected from at least one of the group consisting of silicon oxide and silicon nitride.

5. The method of claim 1 including the step of forming a protective layer over the dielectric, passivation layer.

6. The method of claim 2 including the step of forming a protective layer over the dielectric, passivation layer.

7. The method of claim 3 including the step of forming a protective layer over the dielectric, passivation layer.

8. The method of claim 4 including the step of forming a protective layer over the dielectric, passivation layer.

9. A method of forming passivation and protective layers over a metallic structure on a substrate comprising the steps as follows:
coating the metallic on the substrate with a thin film of a low stress modulus polymeric buffer material,
forming a dielectric passivation layer covering the low stress modulus polymeric buffer material, and
forming a protective layer over the dielectric passivation layer.

10. The method of claim 9 wherein the low stress modulus polymeric buffer material is composed of a layer of a material selected from at least one of the group consisting of polyimide, a polymer resin, and members of the hydrogen/alkane SQ (SilsesQuioxane) family.

11. The method of claim 9 wherein the dielectric, passivation layer is composed of at least one layer of a material selected from at least one of the group consisting of silicon oxide and silicon nitride.

12. The method of claim 9 wherein:
the low stress modulus polymeric buffer material is composed of a layer of a material selected from at least one of the group consisting of polyimide, a polymer resin, and members of the hydrogen/alkane SQ (SilsesQuioxane) family, and
the dielectric, passivation layer is composed of at least one layer of a material selected from at least one of the group consisting of silicon oxide and silicon nitride.

13. The method of claim 9 including the step of forming a protective layer over the dielectric, passivation layer.

14. The method of claim 10 including the step of forming a protective layer over the dielectric, passivation layer.

15. The method of claim 11 including the step of forming a protective layer over the dielectric, passivation layer.

16. The method of claim 12 including the step of forming a protective layer over the dielectric, passivation layer.

17. The method of claim 1 wherein the low stress modulus buffer material has a thermal coefficient of expansion between the metallic structure and the dielectric passivation layer.

18. The method of claim 1 wherein the dielectric passivation layer between the metallic structure and the low stress modulus buffer material has a thermal coefficient of expansion between about 5 ppm/° C. and about 20 ppm/° C.

19. The method of claim 9 wherein the low stress modulus buffer material has a thermal coefficient of expansion between the metallic structure and the dielectric passivation layer.

20. The method of claim 9 wherein the dielectric passivation layer between the metallic structure and the low stress modulus buffer material has a thermal coefficient of expansion between about 5 ppm/° C. and about 20 ppm/° C.

21. A structure with reduced stress between a dielectric, passivation layer and a metallic structure comprising:
a low stress modulus buffer material coating the metallic structure, and
a dielectric passivation layer covering the low stress modulus buffer material.

22. The structure of claim 21 wherein the low stress modulus buffer material is composed of a layer of a material selected from at least one of the group consisting of polyimide, a polymer resin, and members of the hydrogen/alkane SQ (SilsesQuioxane) family.

23. The structure of claim 21 wherein the dielectric, passivation layer is composed of at least one layer of a material selected from at least one of the group consisting of silicon oxide and silicon nitride.

24. The structure of claim 21 wherein:
the low stress modulus buffer material is composed of a layer of a material selected from at least one of the group consisting of polyimide, a polymer resin, and members of the hydrogen/alkane SQ (SilsesQuioxane) family, and
the dielectric, passivation layer is composed of at least one layer of a material selected from at least one of the group consisting of silicon oxide and silicon nitride.

25. The structure of claim 21 including a protective layer formed over the dielectric, passivation layer.

26. The structure of claim 18 including a protective layer formed over the dielectric, passivation layer.

27. The structure of claim 26 including a protective layer formed over the dielectric, passivation layer.

28. The structure of claim 24 including a protective layer formed over the dielectric, passivation layer.

29. A structure including a dielectric passivation layer and a protective layer formed over a metallic structure on a substrate comprising:
a metallic coating formed on the substrate comprising a thin film of a low stress modulus polymeric material,
a dielectric passivation layer formed over the low stress modulus polymeric material, and
a protective layer formed over the dielectric passivation layer.

30. The structure of claim 29 wherein the low stress modulus buffer material is composed of a layer of a material selected from at least one of the group consisting of polyimide, a polymer resin, and members of the hydrogen/alkane SQ (SilsesQuioxane) family.

31. The structure of claim 30 wherein the dielectric, passivation layer is composed of at least one layer of a material selected from at least one of the group consisting of silicon oxide and silicon nitride.

32. The structure of claim 30 wherein:
the low stress modulus buffer material is composed of a layer of a material selected from at least one of the group consisting of polyimide, a polymer resin, and members of the hydrogen/alkane SilsesQuioxane (SQ) family, and
the dielectric, passivation layer is composed of at least one layer of a material selected from at least one of the group consisting of silicon oxide and silicon nitride.

33. The structure of claim 30 including a protective layer formed over the dielectric, passivation layer.

34. The structure of claim 31 including a protective layer formed over the dielectric, passivation layer.

35. The structure of claim 32 including a protective layer formed over the dielectric, passivation layer.

36. The structure of claim 33 including a protective layer formed over the dielectric, passivation layer.

37. The structure of claim 21 wherein the low stress modulus buffer material has a thermal coefficient of expansion between the metallic structure and the dielectric passivation layer.

38. The structure of claim 21 wherein the dielectric passivation layer between the metallic structure and the low stress modulus buffer material has a thermal coefficient of expansion between about 5 ppm/° C. and about 20 ppm/° C.

39. The structure of claim 25 wherein the low stress modulus buffer material has a thermal coefficient of expansion between the metallic structure and the dielectric passivation layer.

40. The structure of claim 25 wherein the dielectric passivation layer between the metallic structure and the low stress modulus buffer material has a thermal coefficient of expansion between about 5 ppm/° C. and about 20 ppm/° C.
